(19) United States
(12) Patent Application Publication
(10) Pub. No.: US 2013/0075882 A1
(43) Pub. Date: Mar. 28, 2013

(54) PACKAGE STRUCTURE

(71) Applicants: KUO-CHIANG CHEN, New Taipei City (TW); ARTHUR SHAOYAN RONG, Taipei City (TW); CHEN HSING LIU, Taoyuan County (TW); YEN-YI CHEN, New Taipei City (TW)

(72) Inventors: KUO-CHIANG CHEN, New Taipei City (TW); ARTHUR SHAOYAN RONG, Taipei City (TW); CHEN HSING LIU, Taoyuan County (TW); YEN-YI CHEN, New Taipei City (TW)

(73) Assignee: FORTUNE SEMICONDUCTOR CORPORATION, NEW TAIPEI CITY (TW)

(21) Appl. No.: 13/244,410

(22) Filed: Sep. 24, 2011

(51) Int. Cl. H01L 23/495

(52) U.S. Cl. 257/675; 257/676; 257/E23.044

(57) ABSTRACT

A package structure including a first leadframe, a second leadframe, a power pin, a ground pin, a first pin, several first wires, several second wires, and a package body is disclosed. The first leadframe is used for electrically coupling to the drains of a first power transistor and the second power transistor. The ground pin is electrically coupled to the first leadframe. The first pin is connected with the first leadframe through a conductive region used for increasing the amount of current which can be loaded by the first pin. The first wires are used for electrically coupling between the first leadframe and the source of the second power transistor, for reducing the internal resistance of the second power transistor. The second wires are used for electrically coupling between the ground pin and the source of the first power transistor, for reducing the internal resistance of the first power transistor.

### BACKGROUND OF THE INVENTION

1. Field of the Invention

The present invention relates to a package structure; in particular, to a package structure of a lithium battery protection circuit.

2. Description of Related Art

Please refer to FIG. 1 which is a circuit diagram of a conventional single-cell lithium battery protection circuit. The single-cell lithium battery mainly includes a single-cell lithium battery (or so called a battery core) and a single-cell lithium battery protection panel. The single-cell lithium battery protection panel 1 includes resistors R1 and R2, a capacitor C1, and an integrated circuit 10 which is welds with a chip having a first power transistor M1 and a second power transistor M2, as shown in FIG. 1. Generally, a package structure 11 of the integrated circuit 10 may be small outline transistor package with six pins (SOT26). The first power transistor M1 and the second power transistor M2 are power metal-oxide-semiconductor field-effect transistors (MOSFET), and a package structure 12 of the first power transistor M1 and the second power transistor M2 may usually be thin-shrink small outline package with eight pins (TSSOP-8). The load is electrically coupled to the pins BATP and BATN.

The coupling manners of the integrated circuit 10 packaged by the package structure 11 and the first power transistor M1 and the second power transistor M2 packaged by the package structure 12 are described as follows. The integrated circuit 10 has several pins VCC, GND, OD, OC, and CS. The pins VCC and GND are used for electrically coupling to a lithium battery, and the pins OD and OC are used for electrically coupling to the control terminals (gates) of the power transistors M1 and M2. The pin CS is used as a detection terminal of over current protection of the integrated circuit 10. However, the package manner which separately packages the integrated circuit 10 and the power transistors M1 and M2 may have the problems of high manufacturing cost and large package areas.

### SUMMARY OF THE INVENTION

The object of the present invention is to provide a package structure, for reducing the area of packaging a lithium battery protection circuit and the packaging cost. Thus, the package structure may be used in small and light electronic devices.

An embodiment of the present invention provides a package structure which includes a first leadframe, a second leadframe, a power pin, a ground pin, a first pin, a plurality of first wires, a plurality of second wires, and a package body. The first leadframe is used for placing an integrated circuit. The second leadframe is used for placing a first power transistor and a second power transistor, and for electrically coupling the drains of the first power transistor and the second power transistor. The power pin is used for electrically coupling to the integrated circuit. The ground pin is used for electrically coupling to the first leadframe. The first pin is connected with the first leadframe, and the connecting part between the first pin and the first leadframe has a conductive region used for increasing a current amount which can be loaded by the first pin. The first wires are used for electrically coupling between the first leadframe and the source of the second power transistor, and for reducing an internal resistance of the second power transistor. The second wires are used for electrically coupling between the ground pin and the source of the first power transistor, and for reducing an internal resistance of the first power transistor. The package body is used for covering the first leadframe, the second leadframe, the first wires, the second wires, the integrated circuit, the first power transistor, and the second power transistor, and for partially covering the power pin, the ground pin, and the first pin.

On the basis of the above, the package structure disclosed by the embodiments of the present invention may efficiently simplify the conventional single-cell lithium battery protection application circuit. By packaging the power transistors and the integrated circuit in the same package structure, the cost may be reduced. Therefore, the packaging structure may have more competitiveness in the market.

For further understanding of the present disclosure, reference is made to the following detailed description illustrating the embodiments and examples of the present disclosure. The description is only for illustrating the present disclosure, not for limiting the scope of the claim.

### BRIEF DESCRIPTION OF THE DRAWINGS

The drawings included herein provide further understanding of the present disclosure. A brief introduction of the drawings is as follows:

FIG. 1 shows a circuit diagram of a conventional single-cell lithium battery protection circuit;

FIG. 2A shows a schematic diagram of the location of a contact pad of an integrated circuit of a package structure according to an embodiment of the present invention;

FIG. 2B shows an aerial view of pins of a first power transistor and a second power transistor of a package structure according to an embodiment of the present invention;

FIG. 2C shows a dorsal view of pins of a first power transistor and a second power transistor of a package structure according to an embodiment of the present invention;

FIG. 2D shows a perspective view of a package structure according to an embodiment of the present invention;

FIG. 3A shows an aerial view of the external appearance of a package structure according to an embodiment of the present invention;

FIG. 3B shows a dorsal view of the external appearance of a package structure according to an embodiment of the present invention;

FIG. 4A shows a schematic diagram of the location of a contact pad of an integrated circuit of a package structure according to another embodiment of the present invention;

FIG. 4B shows an aerial diagram of pins of a first power transistor and a second power transistor of a package structure according to another embodiment of the present invention; and

FIG. 4C shows a perspective diagram of a package structure according to another embodiment of the present invention.

### DETAILED DESCRIPTION OF THE PREFERRED EMBODIMENTS

### An Embodiment of Package Structure

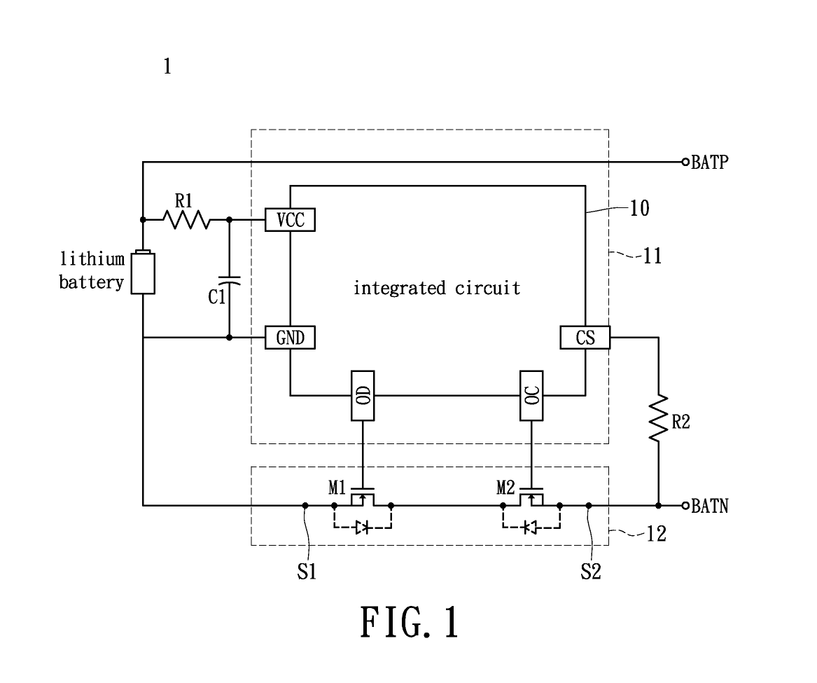

Please refer to FIG. 1 again. The present embodiment packages the integrated circuit 10, the first power transistor M1, and the second power transistor M2 in the same package structure. For easily understanding of the packaging structure of this embodiment, the pins and contact pads of the integrated circuit 10, the first power transistor M1, and the second power transistor M2 may be described in the first place.

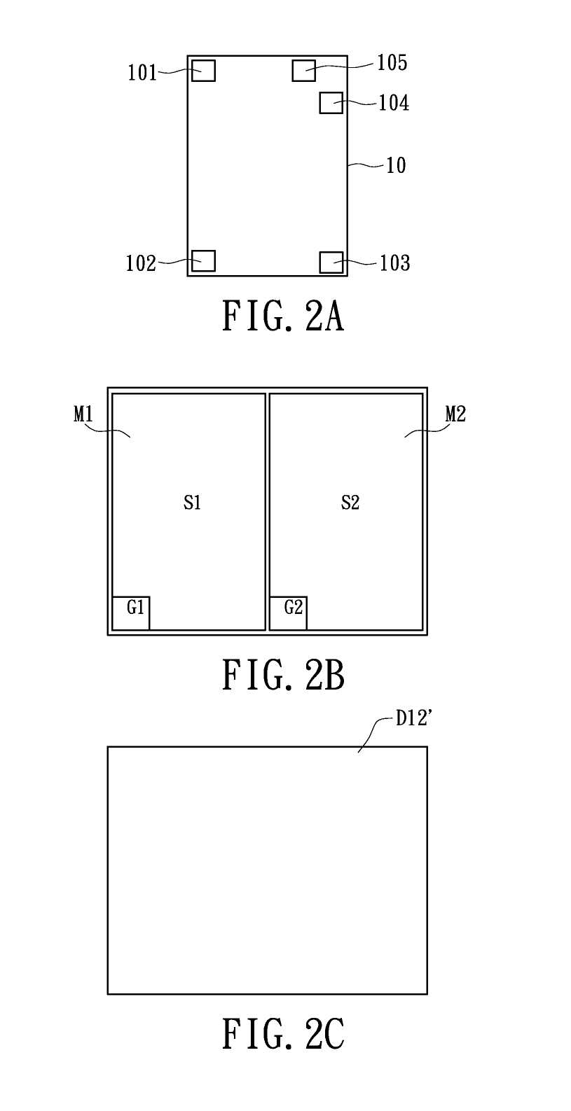

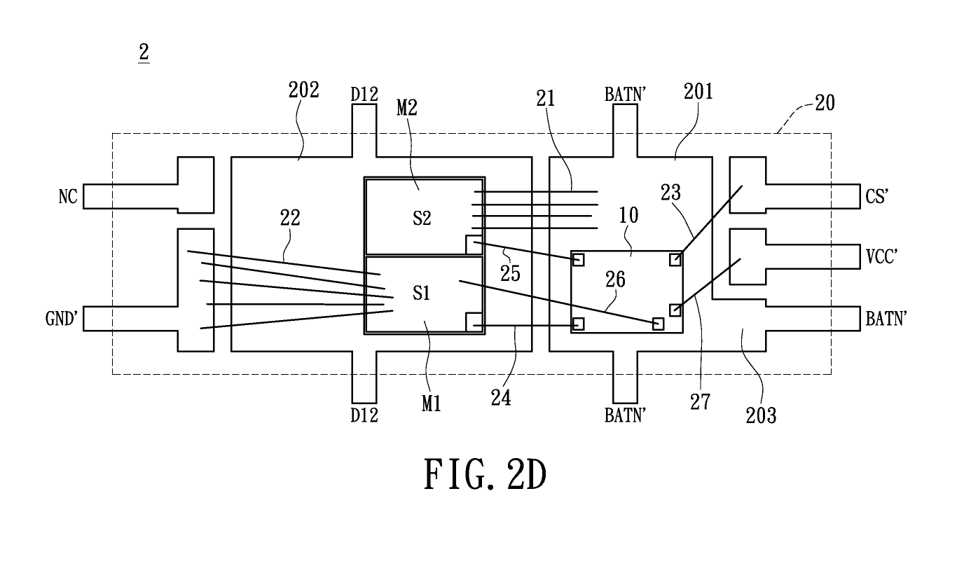

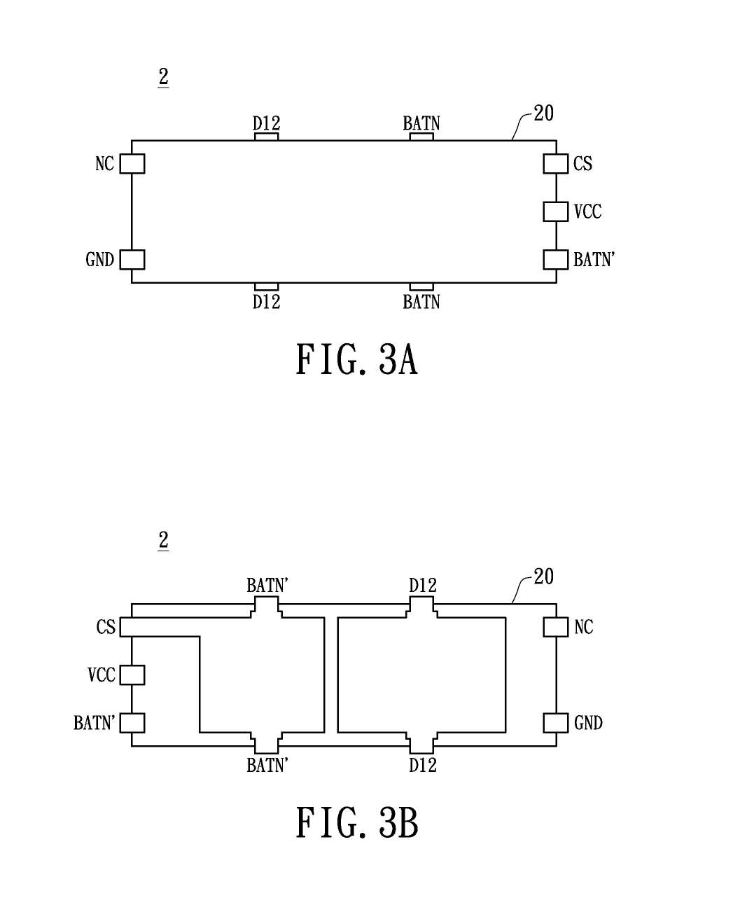

Please refer to FIG. 1 and FIG. 2A at the same time. FIG. 2A shows a schematic diagram of contact pads of the integrated circuit of the package structure according to an embodiment of the present invention. The first contact pad 101 in FIG. 2A is in correspondence to a pin CS of the integrated circuit 10. A first control contact pad 103 and a second control contact pad 102 are in correspondence to pins OD and OC of the integrated circuit 10 respectively. The ground contact pad 104 and the power contact pad 105 are in correspondence to pins GND and VCC of the integrated circuit 10 respectively.

Please refer to FIG. 1 and FIG. 2B simultaneously. FIG. 2B is an aerial diagram of the first power transistor and the second power transistor of the package structure according to an embodiment of the present invention. The source 51 of the first power transistor M1 has relatively larger area, for allowing high current to pass through. Comparing with the source S1 of the first power transistor M1, the control terminal (gate G1) of the first power transistor M1 has relatively smaller area. Similarly, in the second power transistor M2, the area of the source S2 is also larger than the area of the gate G2, for allowing high current to pass through. It is worth noting that during the manufacturing processes, the first power transistor M1 and the second power transistor M2 are usually connected together as a single chip.

Please refer to FIG. 1 and FIG. 2C simultaneously. FIG. 2C shows a dorsal diagram of the contact pad of the first power transistor and the second power transistor of the package structure according to an embodiment of the present invention. The drains of the first power transistor M1 and the second power transistor M2 share the contact pad D12′, for allowing relatively higher current to pass through.

Please refer to FIG. 1 and FIG. 2D simultaneously. FIG. 2D is a perspective diagram of a package structure of a lithium battery protection circuit according to an embodiment of the present invention. The package structure 2 in this embodiment is dual flat no lead package with five pins (DFN-5). The package structure 2 includes a first leadframe 201, a second leadframe 202, a ground pin GND′, a first pin BATN′, a plurality of first wires 21, and a plurality of second wires 22. In addition, the package structure 2 further includes a power pin VCC′, a second pin CS′, and third to seventh wires 23 to 27. It's worth noting that the pin D12 and first pins BATN′ at the up and down side of FIG. 2D are usually unused (which are just the pins of DFN-5 standard), and may practically be omitted.

The first leadframe 201 may be used for placing the integrated circuit 10. The second leadframe 202 may be used for placing the first power transistor M1 and the second power transistor M2, and for electrically connecting with the drains of the first power transistor M1 and the second power transistor M2 through the contact pad D12′. The way of placing the first power transistor M1 and the second power transistor M2 may let the gate G1 and the gate G2 be closing to the first leadframe 201. The ground pin GND′ is electrically coupled to the source S1 of the first power transistor M1 through several second wires 22. The first pin BATN′ has a conductive region 203 used for increasing the current amount which can be loaded by the first pin BATN′. The first wires 21 are used for electrically coupling between the source S2 of the second power transistor M2 and the first leadframe 201.

The second pin CS′ is used for electrically coupling to the first contact pad 101 of the integrated circuit 10 through a third wire 23. A fourth wire 24 is used for electrically coupling between the first control contact pad 103 of the integrated circuit 10 and the gate G1 of the first power transistor M1. A fifth wire 25 is used for electrically coupling between the second control contact pad 102 of the integrated circuit 10 and the gate G2 of the second power transistor M2. The source 51 of the first power transistor M1 is electrically coupled to the ground contact pad 104 of the integrated circuit 10 through a sixth wire 26. The two power pins VCC′ are next to each other and are electrically coupled to each other through a wire 28. The two power pins VCC′ are electrically coupled to the power contact pad 105 of the integrated circuit 10 through a seventh wire 27.

In addition, the package structure 2 may further include a package body 20, for covering the first leadframe 201, the second leadframe 202, the integrated circuit 10, the first power transistor M1, the second power transistor M2, and the first to seventh wires 21 to 27. The package body 20 may partially cover the ground pin GND′, the power pin VCC′, the first pin BATN′, the second pin CS′, and the pin D12. The package body 20 may be formed by solid molding package materials which mainly include epoxy resin, hardening agent, silicon dioxide, and catalyst, etc. The commonly used hardening agent is bakelite. The silicon dioxide may have the capability of reducing thermal expansion coefficient. For mold releasing after package molding, a small amount of wax may be added as mold releasing agent, but the present invention is not limited thereby.

Please refer to FIG. 2D again. The configurations of the pins may be associated with the first to seventh wires 21 to 27. According to different arrangements of the single-cell lithium battery protection circuit and the metal-oxide-semiconductor field-effect transistors (MOSFET), different package manners may be defined, which may let the single-cell lithium battery protection circuit with power transistors be packaged in a DFN-5 package. The embodiment of the present invention is one of the preferred package manners.

The number of the several first wires 21 of the package structure 20 is associated with the internal resistances seen from the first pin BATN′ and the ground pin GND′. For reducing the internal resistances of the first pin BATN′ and the ground pin GND′, the wire bonding manners of the two pins are as the first to seventh wires 21 to 27 shown in FIG. 2D. In addition, the numbers of the second wires 22 connecting with the ground pin GND′ and the first wires 21 connecting with the first leadframe 201 may be adjusted according to the sizes of the package structure and the leadframes, which may be one to more than ten. Therefore, the internal resistances of the first power transistor M1 and the second power transistor M2 may be improved. In other words, the first wires 21 and the second wires 22 are used for reducing the internal resistances of the first power transistor M1 and the second power transistor M2 respectively.

Please refer to FIG. 1 and FIG. 2D again. In the package structure 2 of FIG. 2D, the current path is from the ground pin GND′ to the second wires 22, and then to the control terminal (source S1) of the first power transistor M1. Then, the current may flow from the first power transistor M1 to the second power transistor M2 through the contact pad D12′ which is shared by the first power transistor M1 and the second power transistor M2. After that, the current may flow from the source S2 of the second power transistor M2 to the first leadframe 201 through the first wires 21, and then to the first pin BATN′. Therefore, under the consideration of heat dissipation, the pins which carry large amount of current may use the leadframe to dissipate heat.

The package structure in this embodiment may use conductive adhesive for connecting the pins carrying large amount of current to the leadframes. For example, the first pin BATN′ is connected with the first leadframe 201 which may usually have substrate or base for enhancing the efficiency of heat dissipation, and for preventing the integrated circuit 10 from being damaged because of overheating. When the lithium battery is charging, the current may flow from the ground pin GND′ to the second leadframe 202 through the first power transistor M1, and to the first leadframe 201 and the first pin BATN′ through the second power transistor M2. On the other hand, when the battery is discharging, the current may flow from the first pin BATN′ to the second leadframe 202 through the second power transistor M2, and to the ground pin GND′ through the first power transistor M1. Thus, the large amount of current which passes through the first leadframe 201 and the second leadframe 202 may be heat-dissipated by the first leadframe 201 and the second leadframe 202. Generally, the first leadframe 201 and the second leadframe 202 have substrates or bases which enhance the heat dissipating capabilities of the first leadframe 201 and the second leadframe 202. It is worth noting that the base or substrate of the leadframe may be connected with the leadframe by using conductive adhesive. Moreover, according to the actual requirements, the bases or substrates may be conductive materials (which are usually metals) which are directly connected with the leadframes.

The numbers of the first wires 21 and the second wires 22 may influence the internal resistances of the first power transistor M1 and the second power transistor M2. For illustrating the influences of the number of the wires to the internal resistances, the following description shows the corresponding internal resistance of each number of wires. Under the situation that the measurement terminals are from the pin D12 to the ground pin GND′ of the package structure, the average resistance may be 17.39 ohms (the second wires 22 are six strips of 1.5 mils of copper wires), 17.91 ohms (the second wires 22 are five strips of 1.5 mils of copper wires), 18.67 ohms (the second wires 22 are four strips of 1.5 mils of copper wires), 19.69 ohms (the second wires 22 are three strips of 1.5 mils of copper wires), and the standard error of the resistances may be 0.3 ohms. Under the situation that the measurement terminals are from the pin D12 to the first pin BATN′ of the package structure, the average resistance may be 18.01 ohms (the first wires 21 are six strips of 1.5 mils of copper wires), 17.85 ohms (the first wires 21 are five strips of 1.5 mils of copper wires), 18.79 ohms (the first wires 21 are four strips of 1.5 mils of copper wires), 20.07 ohms (the first wires 21 are three strips of 1.5 mils of copper wires). Therefore, we may know that the resistances of the sources of the first power transistor M1 and the second power transistor M2 may decrease when the number of wires increases. That is, the larger the numbers of the first wires 21 and the second wires 22 are, the smaller the internal resistances will be. In addition, for achieving lower resistance, the thread diameters of the first wires 21 and the second wires 22 may be 1.5 to 2 mils.

[Another Embodiment of Package Structure]

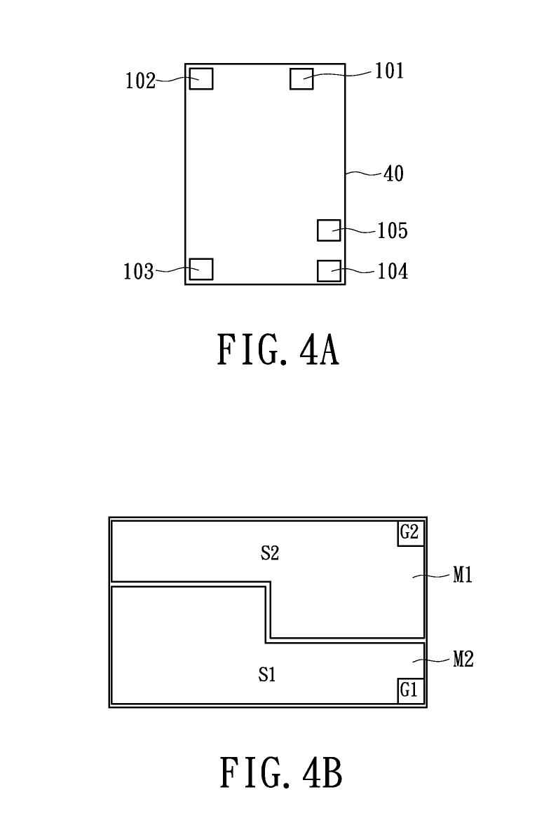

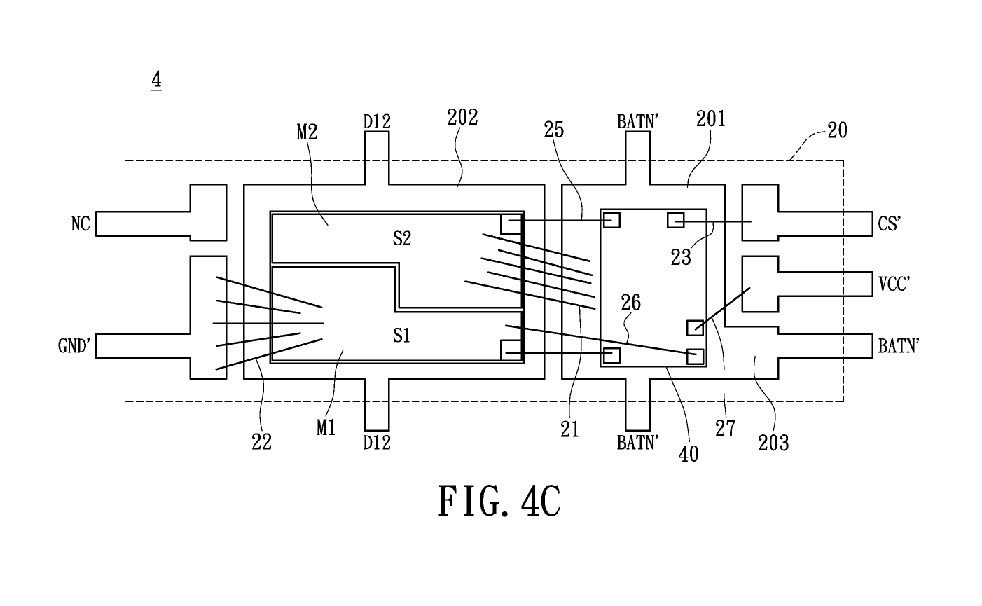

Please refer to FIGS. 4A to 4C at the same time. FIG. 4A is a schematic diagram of the location of contact pads of an integrated circuit of the package structure according to another embodiment of the present invention.

FIG. 4B is an aerial diagram of pins of a first power transistor and the second power transistor of the package structure according to another embodiment of the present invention. FIG. 4C is a perspective diagram of the package structure according to another embodiment of the present invention. The package structure 4 includes the first leadframe 201, the second leadframe 202, the ground pin GND′, the first pin BATN′, the first wires 21, and the second wires 22. In addition, the package structure further includes the power pin VCC′, the second pin CS′, the pin D12, and the third to seventh wires 23 to 27.

The package structure 4 in this embodiment is approximately the same as the package structure 2 (as shown in FIG. 2D), and the differences between them are that the locations of the contact pads of the integrated circuit 40 are not the same. The relative positions between the contact pads does not change, but they may be moved according to the positions of the sources and gates of the power transistors in FIG. 4B. In other words, the locations of the contact pads of the integrated circuit 40 may be acquired by rotating the locations of the contact pads of the integrated circuit 10 clockwise or counterclockwise, as long as the third to fifth wires 21 to 25 do not stride across the seventh wire 27.

The locations of the sources S1 and S2 of the first power transistor M1 and the second power transistor M2 in FIG. 4B and the locations of the gates G1 and G2 of the first power transistor M1 and the second power transistor M2 are away from each other. It is worth noting that after the locations of the gates G1 and G2 are decided, the first wires 21 and the fifth wire 25 cannot stride across, for reducing the resistance and the length of the second wire 22. The remaining parts of the package structure 4 may be shown in the former embodiments, and may not be described repeatedly.

[Possible Efficacy of the Embodiments]

According to the embodiments of the present invention, the aforementioned package structure may be thin and small by packaging the lithium battery protection circuit chip having single-cell lithium battery protection circuit and power transistors into DFN-5 package. In addition, the cost may also be reduced, which makes the package structure much more competitive in the market.

Some modifications of these examples, as well as other possibilities will, on reading or having read this description, or having comprehended these examples, will occur to those skilled in the art. Such modifications and variations are comprehended within this disclosure as described here and claimed below. The description above illustrates only a relative few specific embodiments and examples of the present disclosure. The present disclosure, indeed, does include various modifications and variations made to the structures and operations described herein, which still fall within the scope of the present disclosure as defined in the following claims.

What is claimed is:

1. A package structure comprising:
a first leadframe, for placing an integrated circuit;
a second leadframe, for placing a first power transistor and a second power transistor, and for electrically coupling drains of the first power transistor and the second power transistor;
a power pin, for electrically coupling to the integrated circuit;
a ground pin coupled to the first leadframe;
a first pin connected with the first leadframe, wherein a conductive region locates at a connecting part of the first pin and the first leadframe, and the conductive region is used for increasing a current amount which can be loaded by the first pin;
a plurality of first wires, for electrically coupling between the first leadframe and a source of the second power transistor, and for reducing an internal resistance of the second power transistor;
a plurality of second wires, for electrically coupling between the ground pin and a source of the first power transistor, and for reducing an internal resistance of the first power transistor; and
a package body, for covering the first leadframe, the second leadframe, the first wires, the second wires, the integrated circuit, the first power transistor, and the second power transistor, and for partially covering the power pin, the ground pin, and the first pin.

2. The package structure according to claim 1, further comprising:
a second pin, for electrically coupling to a first contact pad of the integrated circuit through a third wire.

3. The package structure according to claim 2, further comprising:
a fourth wire, for electrically coupling between a first control contact pad of the integrated circuit and a gate of the first power transistor; and
a fifth wire, for electrically coupling between a second control contact pad of the integrated circuit and a gate of the second power transistor.

4. The package structure according to claim 1, wherein thread diameters of the first wires and the second wires are between 1.5 to 2 mils.

5. The package structure according to claim 3, further comprising:
a sixth wire, for electrically coupling between a ground contact pad of the integrated circuit and the source of the first power transistor.

6. The package structure according to claim 5, wherein the power pin is used for electrically coupling to a power contact pad of the integrated circuit through a seventh wire.

7. The package structure according to claim 1, wherein the package structure is a dual flat no lead package with five pins (DFN-5).

8. The package structure according to claim 1, wherein the drains of the first power transistor and the second power transistor is connected with the second leadframe through a source contact pad.

9. The package structure according to claim 1, wherein the integrated circuit is adhered to the first leadframe, and the first power transistor and the second power transistor are adhered to the second leadframe.

10. The package structure according to claim 1, wherein the first leadframe and the second leadframe are used for dissipating heat.
